(19) United States
(12) Patent Application Publication
(10) Pub. No.: US 2023/0127104 A1
(43) Pub. Date: Apr. 27, 2023

(54) TRANSPARENT ELECTROCONDUCTIVE FILM

(71) Applicant: NITTO DENKO CORPORATION, Ibaraki-shi, Osaka (JP)

(72) Inventor: Keita Usui, Osaka (JP)

(73) Assignee: NITTO DENKO CORPORATION, Ibaraki-shi, Osaka (JP)

(21) Appl. No.: 17/912,182

(22) PCT Filed: Mar. 18, 2021
(86) PCT No.: PCT/JP2021/011163

§ 371 Date: Sep. 16, 2022

(30) Foreign Application Priority Data
Mar. 19, 2020 (JP) 2020-049864
Apr. 20, 2020 (JP) 2020-074853
Apr. 20, 2020 (JP) 2020-074854
Aug. 7, 2020 (JP) 2020-134832
Aug. 7, 2020 (JP) 2020-134833
Aug. 21, 2020 (JP) 2020-140238
Aug. 21, 2020 (JP) 2020-140239
Aug. 21, 2020 (JP) 2020-140240
Aug. 21, 2020 (JP) 2020-140241
Sep. 4, 2020 (JP) 2020-149474
Oct. 29, 2020 (JP) 2020-181349
Dec. 2, 2020 (JP) 2020-200421
Dec. 2, 2020 (JP) 2020-200422

(51) Int. Cl. H01B 5/14

(52) U.S. Cl. CPC H01B 5/14

(57) ABSTRACT

A transparent electroconductive film (X) includes a transparent resin substrate (10) and a transparent electroconductive layer (20) in this order in a thickness direction (T). The transparent electroconductive layer (20) has, in an in-plane direction orthogonal to the thickness direction (T), a first direction in which a compressive residual stress is maximum, and a second direction orthogonal to the first direction. In the transparent electroconductive layer (20), a ratio of a second compressive residual stress in the second direction to a first compressive residual stress in the first direction is 0.82 or more.

### TECHNICAL FIELD

The present invention relates to a transparent electroconductive film.

### BACKGROUND ART

Conventionally, a transparent electroconductive film sequentially including a transparent substrate film and a transparent electrically conductive layer (transparent electroconductive layer) in the thickness direction has been known. The transparent electroconductive layer is used as, for example, a conductor film for forming a pattern of a transparent electrode in various devices such as a liquid crystal display, a touch panel, and an optical sensor. In the process of forming the transparent electroconductive layer, for example, first, an amorphous film of a transparent electroconductive material is formed on a substrate film by a sputtering method (film deposition step). Next, the amorphous transparent electroconductive layer on the substrate film is crystallized by heating (crystallization step). The technique relating to the transparent electroconductive film is described in, for example, Patent Document 1 below.

### CITATION LIST

### Patent Document

Patent Document 1: Japanese Unexamined Patent Publication No. 2017-71850

### SUMMARY OF THE INVENTION

### Problem to be Solved by the Invention

A residual stress is generated in portions of the transparent electroconductive film through the crystallization step. In such transparent electroconductive film, for example, warpage occurs to release the residual stress. The occurrence of warpage is not preferred in order to precisely assemble the transparent electroconductive film in the process of producing a device, for example.

The present invention relates to a transparent electroconductive film suitable for suppressing warpage.

### Means for Solving the Problem

The present invention [1] include a transparent electroconductive film including a transparent resin substrate and a transparent electroconductive layer in this order in a thickness direction, in which the transparent electroconductive layer has, in an in-plane direction orthogonal to the thickness direction, a first direction in which a compressive residual stress is maximum, and a second direction orthogonal to the first direction, and in the transparent electroconductive layer, a ratio of a second compressive residual stress in the second direction to a first compressive residual stress in the first direction is 0.82 or more.

The present invention [2] includes the transparent electroconductive film described in [1], wherein the transparent electroconductive layer contains krypton.

The present invention [3] includes the transparent electroconductive film described in [1] or [2], wherein the transparent electroconductive layer contains an indium-containing electroconductive oxide.

The present invention [4] includes the transparent electroconductive film described in any one of the above-described [1] to [3], wherein the transparent electroconductive layer has a specific resistance of less than 2.2×10⁴ Ω·cm.

### Effects of the Invention

In the transparent electroconductive film of the present invention, the transparent electroconductive layer has, in an in-plane direction orthogonal to the thickness direction, a first direction in which a compressive residual stress is maximum, and a second direction orthogonal to the first direction, and in the transparent electroconductive layer, a ratio of a second compressive residual stress in the second direction to a first compressive residual stress in the first direction is 0.82 or more. Therefore, the transparent electroconductive film of the present invention is suitable for suppressing the occurrence of warpage.

### BRIEF DESCRIPTION OF THE DRAWINGS

FIG. 1 is a schematic cross-sectional view of an embodiment of a transparent electroconductive film according to the present invention.

FIG. 2 is a schematic cross-sectional view of a modification of the transparent electroconductive film according to the present invention. In this modification, a transparent electroconductive layer includes a first region and a second region in this order from a transparent resin substrate side.

FIGS. 3A to 3D represents a method of producing the transparent electroconductive film shown in FIG. 1: FIG. 3A represents a step of preparing a resin film, FIG. 3B represents a step of forming a functional layer on the resin film, FIG. 3C represents a step of forming a transparent electroconductive layer on the functional layer, and FIG. 3D represents a step of crystallizing the transparent electroconductive layer.

FIG. 4 represents a case where the transparent electroconductive layer of the transparent electroconductive film shown in FIG. 1 is patterned.

FIG. 5 is a graph showing a relationship between an amount of oxygen introduced when the transparent electroconductive layer is formed by a sputtering method and a surface resistance of the formed transparent electroconductive layer.

### DESCRIPTION OF THE EMBODIMENTS

FIG. 1 is a schematic cross-sectional view of a transparent electroconductive film X as an embodiment of a transparent electroconductive film according to the present invention. The transparent electroconductive film X includes a transparent resin substrate 10 and a transparent electroconductive layer 20 in this order toward one side in a thickness direction T. The transparent electroconductive film X, the transparent resin substrate 10, and the transparent electroconductive layer 20 each have a shape extending in a direction (plane direction) orthogonal to the thickness direction T. The transparent electroconductive film X is one element provided in a touch sensor, a light control element, a photoelectric conversion element, a hot wire control member, an antenna member, an electromagnetic wave shielding member, a heater member, an illuminating device, an image display device, and the like.

The transparent resin substrate 10 includes a resin film 11 and a functional layer 12 in this order toward one side in the thickness direction T. In the present embodiment, the transparent resin substrate 10 has a lengthy shape long in a resin flow direction (MD direction) in the process of producing the resin film 11, and has a width in a direction orthogonal to each of the MD direction and the thickness direction T.

The resin film 11 is a transparent resin film having flexuous property. Examples of a material of the resin film 11 include polyester resin, polyolefin resin, acrylic resin, polycarbonate resin, polyether sulfone resin, polyarylate resin, melamine resin, polyamide resin, polyimide resin, cellulose resin, and polystyrene resin. Examples of the polyester resin include polyethylene terephthalate (PET), polybutylene terephthalate, and polyethylene naphthalate. Examples of the polyolefin resin include polyethylene, polypropylene, and cycloolefin polymer (COP). Examples of the acrylic resin include polymethacrylate. As the material of the resin film 11, in view of transparency and strength, preferably, at least one resin selected from the group consisting of a polyester resin and a polyolefin resin is used, more preferably, at least one resin selected from the group consisting of a COP and a PET is used.

A functional layer 12-side surface of the resin film 11 may be surfaced-modified in a surface modification treatment. Examples of the surface modification treatment include corona treatment, plasma treatment, ozone treatment, primer treatment, glow treatment, and coupling agent treatment.

The resin film 11 has a thickness of preferably 5 μm or more, more preferably 10 μm or more, even more preferably 15 μm or more. This configuration is suitable for ensuring the strength of the transparent electroconductive film X. The resin film 11 has a thickness of preferably 100 μm or less, more preferably 80 μm or less, even more preferably 60 μm or less. This configuration is suitable for ensuring flexibility of the transparent electroconductive film X to achieve good handleability.

The resin film 11 has a total light transmittance (JIS K 7375-2008) of preferably 60% or more, more preferably 80% or more, even more preferably 85% or more. This configuration is suitable for ensuring the transparency required for the transparent electroconductive film X when the transparent electroconductive film X is provided in a touch sensor, a light control element, a photoelectric conversion element, a hot wire control member, an antenna member, an electromagnetic wave shielding member, a heater member, an illuminating device, an image display device, and the like. The resin film 11 has a total light transmittance of, for example, 100% or less.

In the present embodiment, the functional layer 12 is located on one surface in the thickness direction T of the resin film 11. In the present embodiment, the functional layer 12 is a hard coat layer for preventing a scratch from being formed on an exposed surface (upper surface in FIG. 1) of the transparent electroconductive layer 20.

The hard coat layer is a cured product of a curable resin composition. Examples of the resin contained in the curable resin composition include polyester resin, acrylic resin, urethane resin, amide resin, silicone resin, epoxy resin, and melamine resin. Examples of the curable resin composition include an ultraviolet curing type resin composition and a thermosetting type resin composition. As the curable resin composition, an ultraviolet curing type resin composition is preferably used in view of serving to improve production efficiency of the transparent electroconductive film X because it can be cured without heating at a high temperature. As a specific example of the ultraviolet curing type resin composition, a composition for forming a hard coat layer described in Japanese Unexamined Patent Publication No. 2016-179686 is used. The curable resin composition may contain fine particles.

The functional layer 12 serving as the hard coat layer has a thickness of preferably 0.1 μm or more, more preferably 0.3 μm or more, even more preferably 0.5 μm or more. This configuration is suitable for allowing the transparent electroconductive layer 20 to have sufficient scratch resistance. The functional layer 12 serving as the hard coat layer has a thickness of preferably 10 μm or less, more preferably 5 μm or less, even more preferably 3 μm or less in view of ensuring the transparency of the functional layer 12.

A transparent electroconductive layer 20-side surface of the functional layer 12 may be surfaced-modified in a surface modification treatment. Examples of the surface modification treatment include corona treatment, plasma treatment, ozone treatment, primer treatment, glow treatment, and coupling agent treatment.

The transparent resin substrate 10 has a thickness of preferably 5 μm or more, more preferably 10 μm or more, even more preferably 15 μm or more. This configuration is suitable for ensuring the strength of the transparent electroconductive film X. The transparent resin substrate 10 has a thickness of preferably 100 μm or less, more preferably 80 μm or less, even more preferably 60 μm or less. This configuration is suitable for ensuring flexibility of the transparent electroconductive film X to achieve good handleability.

The transparent resin substrate 10 has a total light transmittance (JIS K 7375-2008) of preferably 60% or more, more preferably 80% or more, even more preferably 85% or more. This configuration is suitable for ensuring the transparency required for the transparent electroconductive film X when the transparent electroconductive film X is provided in a touch sensor, a light control element, a photoelectric conversion element, a hot wire control member, an antenna member, an electromagnetic wave shielding member, a heater member, an illuminating device, an image display device, and the like. The transparent resin substrate 10 has a total light transmittance of, for example, 100% or less.

An anti-blocking layer may be provided on a surface of the transparent resin substrate 10 opposite to the transparent electroconductive layer 20. This configuration is preferred in view of preventing the transparent resin substrate 10 when in rolled form from sticking to each other (blocking). The anti-blocking layer can be formed from, for example, a curable resin composition containing fine particles.

In the present embodiment, the transparent electroconductive layer 20 is located on one surface of the transparent resin substrate 10 in the thickness direction T. The transparent electroconductive layer 20 is a crystalline film having both light transmittivity and electroconductivity.

The transparent electroconductive layer 20 is a layer formed of a transparent electroconductive material. The transparent electroconductive material contains, for example, an electroconductive oxide as a main component.

Examples of the electroconductive oxide include metal oxides containing at least one kind of metal or metalloid selected from the group consisting of In, Sn, Zn, Ga, Sb, Ti, Si, Zr, Mg, Al, Au, Ag, Cu, Pd, and W. Specific examples of the electroconductive oxide include an indium-containing electroconductive oxide and an antimony-containing electroconductive oxide. Examples of the indium-containing electroconductive oxide include an indium tin composite oxide (ITO), an indium zinc composite oxide (IZO), an indium gallium composite oxide (IGO), and an indium gallium zinc composite oxide (IGZO). Examples of the antimony-containing electroconductive oxide include an antimony tin composite oxide (ATO). In view of achieving high transparency and good electroconductivity, as the electroconductive oxide, preferably an indium-containing electroconductive oxide is used, more preferably, an ITO is used. Such ITO may contain a metal or a metalloid other than In and Sn in an amount less than the content of each of In and Sn.

When an ITO is used as the electroconductive oxide, the ratio of the content of tin oxide (SnO₂) to the total content of indium oxide (In₂O₃) and tin oxide in the ITO is preferably 1% by mass or more, more preferably 3% by mass or more, even more preferably 5% by mass or more, particularly preferably 7% by mass or more. The ratio of the number of tin atoms to the number of indium atoms (number of tin atoms/number of indium atoms) in the ITO is preferably 0.01 or more, more preferably 0.03 or more, even more preferably 0.05 or more, particularly preferably 0.07 or more. These configurations are suitable for ensuring durability of the transparent electroconductive layer 20. The ratio of the content of tin oxide (SnO₂) to the total content of indium oxide (In₂O₃) and tin oxide in the ITO is preferably 15% by mass or less, more preferably 13% by mass or less, even more preferably 12% by mass or less. The ratio of the number of tin atoms to the number of indium atoms (number of tin atoms/number of indium atoms) in the ITO is preferably 0.16 or less, more preferably 0.14 or less, even more preferably 0.13 or less. These configurations are preferred in view of reducing resistance in the transparent electroconductive layer 20. The ratio of the number of tin atoms to the number of indium atoms in the ITO is determined by, for example, specifying ratios of the indium atom and the tin atom present in an object to be measured by X-ray photoelectron spectroscopy. The above-mentioned content ratio of the tin oxide in the ITO is determined from, for example, such specified ratios of the indium atom and the tin atom present therein. The above-mentioned content ratio of tin oxide in the ITO may also be judged from the content ratio of tin oxide (SnO₂) in an ITO target used during sputtering film formation.

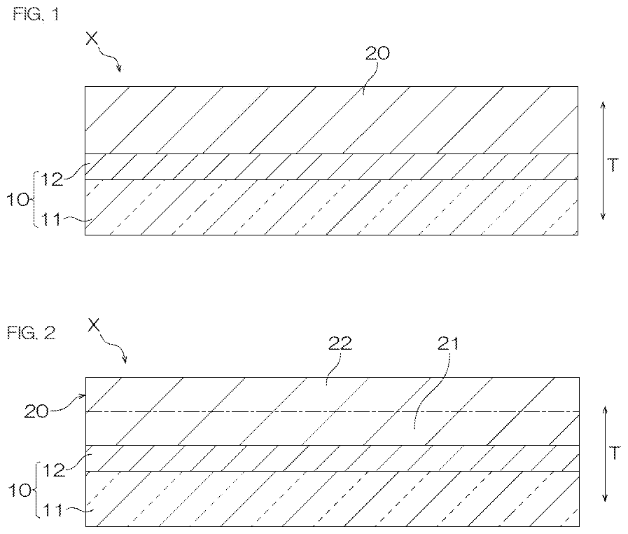

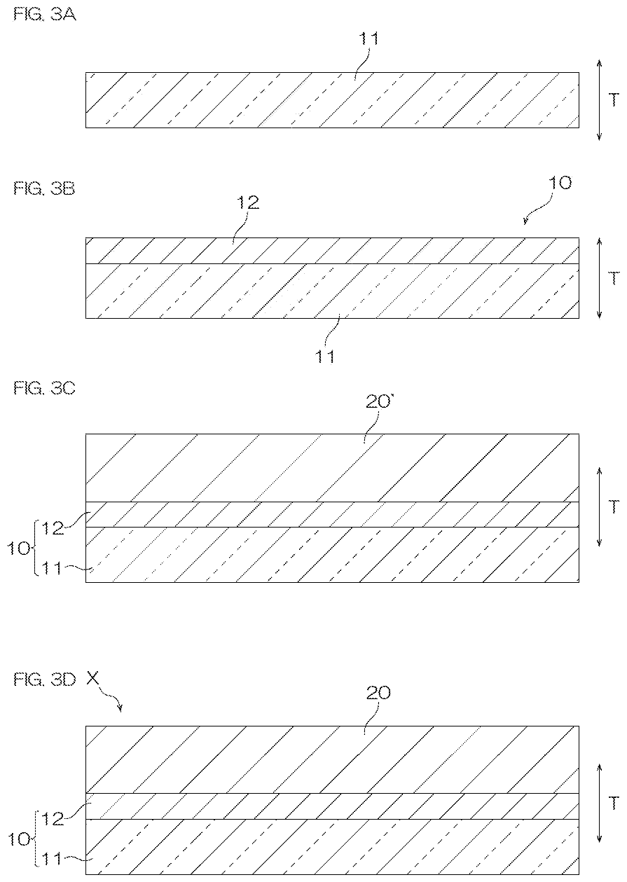

The content ratio of tin oxide in the transparent electroconductive layer 20 may be non-uniform in the thickness direction T. For example, as shown in FIG. 2, the transparent electroconductive layer 20 may include a first region 21 in which the content ratio of tin oxide is relatively high, and a second region 22 in which the content ratio of tin oxide is relatively low, in this order from the transparent resin substrate 10 side. In FIG. 2, a boundary between the first region 21 and the second region 22 is drawn in phantom line. When the composition of the first region 21 and the composition of the second region 22 are not significantly different from each other, the boundary between the first region 21 and the second region 22 cannot be clearly discriminated in some cases.

The content ratio of tin oxide in the first region 21 is preferably 5% by mass or more, more preferably 7% by mass or more, even more preferably 9% by mass or more. The content ratio of tin oxide in the first region 21 is preferably 15% by mass or less, more preferably 13% by mass or less, even more preferably 11% by mass or less. The content ratio of tin oxide in the second region 22 is preferably 0.5% by mass or more, more preferably 1% by mass or more, even more preferably 2% by mass or more. The content ratio of tin oxide in the second region 22 is preferably 8% by mass or less, more preferably 6% by mass or less, even more preferably 4% by mass or less. The proportion of the thickness of the first region 21 in the thickness of the transparent electroconductive layer 20 is preferably 50% or more, more preferably 60% or more, even more preferably 70% or more. The proportion of the thickness of the second region 22 in the thickness of the transparent electroconductive layer 20 is preferably 50% or less, more preferably 40% or less, even more preferably 30% or less. These configurations are preferred in view of reducing resistance in the transparent electroconductive layer 20.

When containing rare gas atoms, the transparent electroconductive layer 20 preferably contains krypton (Kr) as the rare gas atoms. In the present embodiment, the rare gas atoms in the transparent electroconductive layer 20 are derived from rare gas atoms used as a sputtering gas in a sputtering method to be described later. In the present embodiment, the transparent electroconductive layer 20 is a film (sputtered film) formed by the sputtering method.

An amorphous transparent electroconductive layer of a Kr-containing sputtered film is suitable for achieving good crystal growth by heating to form larger crystal grains than an amorphous transparent electroconductive layer of an Ar-containing sputtered film, and thus, suitable for obtaining the transparent electroconductive layer 20 having low resistance (the larger the crystal grains in the transparent electroconductive layer 20, the lower the resistance of the transparent electroconductive layer 20). The presence or absence of Kr in the transparent electroconductive layer 20 is identified by, for example, X-ray fluorescence analysis to be described later regarding Example.

A Kr content ratio in the transparent electroconductive layer 20 is preferably, 0.0001 atomic % or more entirely in the thickness direction T. The transparent electroconductive layer 20 may include a region containing rare gas atoms at a ratio of less than 0.0001 atomic %, at least partially in the thickness direction T (that is, partially in the thickness direction T, the rare gas atoms may be present in a cross section thereof in a plane direction orthogonal to the thickness direction T at a ratio of less than 0.0001 atomic %). The content ratio of Kr in the transparent electroconductive layer 20 is preferably 1 atomic % or less, more preferably 0.5 atomic % or less, even more preferably 0.3 atomic % or less, particularly preferably 0.2 atomic % or less, entirely in the thickness direction T. This configuration is suitable for achieving good crystal growth to form large crystal grains when an amorphous transparent electroconductive layer 20′ to be described later is crystallized by heating to form a crystalline transparent electroconductive layer 20, and is thus suitable for obtaining the transparent electroconductive layer 20 having low resistance.

The content ratio of Kr in the transparent electroconductive layer 20 may be non-uniform in the thickness direction T. For example, in the Kr-containing region, the Kr content ratio may gradually increase or decrease in the thickness direction T depending on the distance from the transparent resin substrate 10. Alternatively, the transparent electroconductive layer 20 may have a partial region on the transparent resin substrate 10 side in which the Kr content ratio gradually increases in the thickness direction T depending on the distance from the transparent resin substrate 10, and a partial region on the opposite side to the transparent resin substrate 10 in which the Kr content ratio gradually decreases in the thickness direction T depending on the distance from the transparent resin substrate 10. Alternatively, the transparent electroconductive layer 20 may have a partial region in which the Kr content ratio gradually decreases in the thickness direction T depending on the distance from the transparent resin substrate 10, and a partial region on the opposite side to the transparent resin substrate 10 in which the Kr content ratio gradually increases in the thickness direction T depending on the distance from the transparent resin substrate 10.

The transparent electroconductive layer 20 has a thickness of, for example, 10 nm or more, preferably 20 nm or more, more preferably 25 nm or more. This configuration is preferred in view of reducing resistance in the transparent electroconductive layer 20. The transparent electroconductive layer 20 has a thickness of, for example, 1000 nm or less, preferably less than 300 nm, more preferably 250 nm or less, even more preferably 200 nm or less, especially preferably 160 nm or less, particularly preferably less than 150 nm, most preferably 148 nm or less. This configuration is suitable for suppressing warpage in the transparent electroconductive film X including the transparent electroconductive layer 20.

The transparent electroconductive layer 20 has a specific resistance of, for example, 2.5×10⁻⁴ Ω·cm or less, preferably less than 2.2×10⁻⁴ Ω·cm, more preferably 2×10⁻⁴ Ω·cm or less, even more preferably 1.8×10⁻⁴ Ω·cm or less, particularly preferably 1.6×10⁻⁴ Ω·cm or less. The transparent electroconductive layer 20 has a specific resistance of preferably 0.1×10⁻⁴ Ω·cm or more, more preferably 0.5×10⁻⁴ Ω·cm or more, even more preferably 1.0×10⁻⁴ Ω·cm or more. These configurations are suitable for ensuring the low resistance required for the transparent electroconductive layer in a touch sensor device, a light control element, a photoelectric conversion element, a hot wire control member, an antenna member, an electromagnetic wave shielding member, a heater member, an illuminating device, an image display device, and the like.

The transparent electroconductive layer 20 has a total light transmittance (JIS K 7375-2008) of preferably 60% or more, more preferably 80% or more, even more preferably 85% or more. This configuration is suitable for ensuring the transparency required for the transparent electroconductive film X when the transparent electroconductive film X is provided in a touch sensor, a light control element, a photoelectric conversion element, a hot wire control member, an antenna member, an electromagnetic wave shielding member, a heater member, an illuminating device, an image display device, and the like. The transparent electroconductive layer 20 has a total light transmittance of, for example, 100% or less.

The transparent electroconductive layer 20 has, in an in-plane direction orthogonal to the thickness direction T, a first direction in which a compressive residual stress is maximum, and a second direction orthogonal to the first direction. In the present embodiment, the first direction is an MD direction of the transparent electroconductive film X (that is, a film travel direction in a production process to be described later by a roll-to-roll system). When the first direction is the MD direction, the second direction is a width direction (TD direction) orthogonal to each of the MD direction and the thickness direction. The direction in which the compressive residual stress in the transparent electroconductive layer 20 is maximum can be specified by, for example, defining an axis extending in an arbitrary direction in the in-plane direction of the transparent electroconductive layer 20 as a reference axis (0°), measuring compressive residual stresses in a plurality of axial directions in 15° increments based on the reference axis, and specifying the direction based on the measurement results.

The transparent electroconductive layer 20 has a compressive residual stress in the first direction (first compressive residual stress) of preferably 700 MPa or less, more preferably 680 MPa or less, even more preferably 650 MPa or less, particularly preferably 620 MPa or less. The first compressive residual stress is, for example, 1 MPa or more. The transparent electroconductive layer 20 has a compressive residual stress in the second direction (second compressive residual stress) of preferably 680 MPa or less, more preferably 650 MPa or less, even more preferably 620 MPa or less, particularly preferably 600 MPa or less, as long as the second compressive residual stress is less than the first compressive residual stress. The second compressive residual stress is, for example, 1 MPa or more, as long as it is less than the first compressive residual stress. These configurations are suitable for reducing a net internal stress in the transparent electroconductive layer 20. Reduction of the compressive residual stress in the transparent electroconductive layer 20 is suitable for suppressing warpage of the transparent electroconductive film X.

A ratio of the second compressive residual stress to the first compressive residual stress is 0.82 or more, preferably 0.84 or more, more preferably 0.86 or more, even more preferably 0.88 or more, particularly preferably 0.9 or more. The ratio thereof is, for example, 1 or less. The first and second compressive residual stresses can be adjusted by, for example, adjusting various conditions prevailing when the transparent electroconductive layer 20 is subjected to sputtering film formation as described later. Examples of the conditions include a temperature of a base where the transparent electroconductive layer 20 is to be deposited (transparent resin substrate 10 in the present embodiment), a tension acting in the travel direction of the transparent resin substrate 10, an amount of oxygen introduced into a film deposition chamber, an atmospheric pressure in the film deposition chamber, and a horizontal magnetic field intensity on a target.

Whether the transparent electroconductive layer is crystalline can be judged as follows, for example. First, a transparent electroconductive layer (in the transparent electroconductive film X, the transparent electroconductive layer 20 on the transparent resin substrate 10) is immersed in hydrochloric acid having a concentration of 5% by mass at 20° C. for 15 minutes. Next, the transparent electroconductive layer is washed with water and then dried. Then, in an exposed plane of the transparent electroconductive layer (in the transparent electroconductive film X, a surface of the transparent electroconductive layer 20 opposite to the transparent resin substrate 10), a resistance between a pair of terminals (inter-terminal resistance) at a separation distance of 15 mm is measured. In this measurement, when the inter-terminal resistance is 10 kΩ or less, the transparent electroconductive layer is crystalline. Whether the transparent electroconductive layer is crystalline can be judged by observing the presence of crystal grains in the transparent electroconductive layer in plane view using a transmission electron microscope.

The transparent electroconductive film X is produced, for example, in the following manner.

First, as shown in FIG. 3A, a resin film 11 is prepared.

Next, as shown in FIG. 3B, a functional layer 12 is formed on one surface in the thickness direction T of the resin film 11. A transparent resin substrate 10 is prepared by the formation of the functional layer 12 on the resin film 11.

The above-mentioned functional layer 12 as a hard coat layer can be formed by applying a coating of a curable resin composition onto the resin film 11 to form a coated film, and then curing the coated film. When the curable resin composition contains an ultraviolet curing type resin, the coated film is cured by ultraviolet irradiation. When the curable resin composition contains a thermosetting type resin, the coated film is cured by heating.

The exposed surface of the functional layer 12 formed on the resin film 11 is subjected to surface modification treatment as needed. When plasma treatment is performed as the surface modification treatment, argon gas is used for example as an inert gas. In the plasma treatment, discharge electric power is, for example, 10 W or more and for example, 5000 W or less.

Next, as shown in FIG. 3C, an amorphous transparent electroconductive layer 20′ is formed on the transparent resin substrate 10. Specifically, a film formation material is deposited on the functional layer 12 in the transparent resin substrate 10 by a sputtering method to form the transparent electroconductive layer 20′.

In the sputtering method, a sputtering film formation apparatus capable of conducting a film deposition process in a roll-to-roll process is preferably used. In the production of the transparent electroconductive film X, in the case of using the roll-to-roll type sputtering film formation apparatus, while a long transparent resin substrate 10 is traveled from a supply roll to a take-up roll included in the apparatus, a film formation material is deposited on the transparent resin substrate 10 to form the transparent electroconductive layer 20′. In the sputtering method, a sputtering film formation apparatus having one film deposition chamber may be used, or a sputtering film formation apparatus having a plurality of film deposition chambers sequentially disposed along a travel path of the transparent resin substrate 10 may be used (when the transparent electroconductive layer 20 including the first region 21 and the second region 22 described above is formed, a sputtering film formation apparatus having a plurality of film deposition chambers is used).

In the sputtering method, specifically, while a sputtering gas (inert gas) is introduced into a film deposition chamber, which is included in the sputtering film formation apparatus, under vacuum conditions, a negative voltage is applied to a target disposed on a cathode in the film deposition chamber. This generates glow discharge to ionize a gas atom, the gas ion is allowed to collide with the target surface at high speed, a target material is sputtered away from the target surface, and the sputtered target material is deposited on the functional layer 12 of the transparent resin substrate 10.

As the material of the target disposed on the cathode in the film deposition chamber, the electroconductive oxide, described above regarding the transparent electroconductive layer 20, is used, an indium-containing electroconductive oxide is preferably used, and an ITO is more preferably used.

As the sputtering gas, Kr is preferably used. The sputtering gas may contain an inert gas other than Kr. Examples of the inert gas other than Kr include rare gas atoms other than Kr. Examples of the rare gas atom other than Kr include Ar and Xe. When the sputtering gas contains an inert gas other than Kr, the content ratio thereof is preferably 50% by volume or less, more preferably 40% by volume or less, even more preferably 30% by volume or less.

The sputtering method is preferably a reactive sputtering method. In the reactive sputtering method, a reactive gas, in addition to the sputtering gas, is introduced into the film deposition chamber.

In the reactive sputtering method, the ratio of the amount of oxygen introduced with respect to the total amount of the sputtering gas and oxygen introduced into the film deposition chamber is, for example, 0.01 flow rate % or more and for example, 15 flow rate % or less.

The atmospheric pressure in the film deposition chamber during film deposition by the sputtering method (sputtering film formation) is, for example, 0.02 Pa or more and for example, 1 Pa or less.

The temperature of the transparent resin substrate 10 during sputtering film formation is, for example, 100° C. or less, preferably 50° C. or less, more preferably 30° C. or less, even more preferably 10° C. or less, particularly preferably 0° C. or less and for example, −50° C. or more, preferably −20° C. or more, more preferably −10° C. or more, even more preferably −7° C. or more.

Examples of a power source for applying a voltage to the target include a DC power source, an AC power source, an MF power source, and an RF power source. As the power source, a DC power source and an RF power source may be used in combination. An absolute value of a discharge voltage during sputtering film formation is, for example, 50 V or more and for example, 500 V or less, preferably 400 V or less.

In the production method, next, as shown in FIG. 3D, the amorphous transparent electroconductive layer 20′ is converted to a crystalline transparent electroconductive layer 20 by heating (crystallization step). Examples of the heating means include an infrared heater, and an oven, such as a heat-medium heating oven and a hot-air heating oven. The environment during heating may be either a vacuum environment or an atmospheric environment. Preferably, heating is performed in the presence of oxygen. The heating temperature is, for example, 100° C. or more, preferably 120° C. or more, in view of ensuring a high crystallization rate. The heating temperature is, for example, 200° C. or less, preferably 180° C. or less, more preferably 170° C. or less, even more preferably 165° C. or less, in view of suppressing the heating effect on the transparent resin substrate 10. The heating time is, for example, 1 minute or more, preferably 5 minutes or more. The heating time is, for example, 300 minutes or less, preferably 120 minutes or less, more preferably 90 minutes or less.

As described above, the transparent electroconductive film X is produced.

The transparent electroconductive film X can be produced, for example, in the above-described manner.

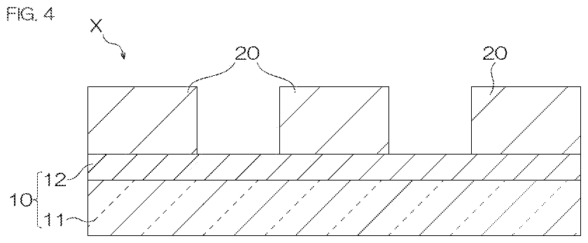

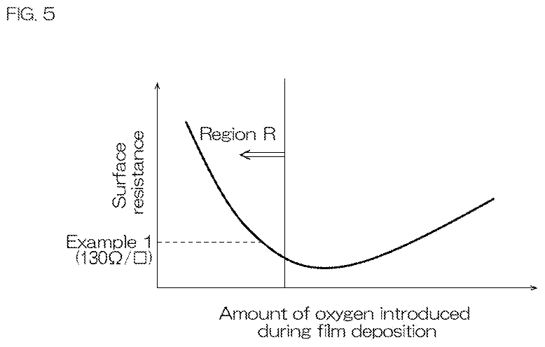

The transparent electroconductive layer 20 in the transparent electroconductive film X may be patterned as schematically shown in FIG. 4. The transparent electroconductive layer 20 can be patterned by etching the transparent electroconductive layer 20 through a predetermined etching mask. The patterned transparent electroconductive layer 20 functions as a wiring pattern, for example. The patterning of the transparent electroconductive layer 20 may be performed before the crystallization step described above.

As described above, the transparent electroconductive film X has, in the in-plane direction orthogonal to the thickness direction, the first direction in which the compressive residual stress is maximum, and the second direction orthogonal to the first direction, and the ratio of the second compressive residual stress in the second direction to the first compressive residual stress in the first direction is 0.82 or more, preferably 0.84 or more, more preferably 0.86 or more, even more preferably 0.88 or more, particularly preferably 0.9 or more. Therefore, in the transparent electroconductive film X, the compressive residual stress (generates in the process of producing the transparent electroconductive film X) in the in-plane direction tends to be isotropically released. The transparent electroconductive film X of such is suitable for suppressing the occurrence of warpage. Examples and Comparative Examples below specifically show this fact.

In the transparent electroconductive film X, the functional layer 12 may be an adhesion improving layer for achieving high adhesion of the transparent electroconductive layer 20 to the transparent resin substrate 10. The configuration in which the functional layer 12 is an adhesion improving layer is suitable for ensuring an adhesive force between the transparent resin substrate 10 and the transparent electroconductive layer 20.

The functional layer 12 may be an index-matching layer for adjusting a reflection coefficient of the surface (one surface in the thickness direction T) of the transparent resin substrate 10. When the transparent electroconductive layer 20 is patterned on the transparent resin substrate 10, the configuration in which the functional layer 12 is an index-matching layer is suitable for making it difficult to visually recognize the pattern shape of the transparent electroconductive layer 20.

The functional layer 12 may be a peel functional layer for allowing the transparent electroconductive layer 20 to be practically peeled off from the transparent resin substrate 10. The configuration in which the functional layer 12 is a peel functional layer is suitable for peeling off the transparent electroconductive layer 20 from the transparent resin substrate 10 to transfer the transparent electroconductive layer 20 to the other member.

The functional layer 12 may be a composite layer in which a plurality of layers are continuous in the thickness direction T. The composite layer preferably includes two or more layers selected from the group consisting of a hard coat layer, an adhesion improving layer, an index-matching layer, and a peel functional layer. This configuration is suitable for exhibiting the above-described functions of the selected layers in the functional layer 12 in a composite manner. In a preferred embodiment, the functional layer 12 includes an adhesion improving layer, a hard coat layer, an index-matching layer in this order toward one side in the thickness direction T on the resin film 11. In another preferred embodiment, the functional layer 12 includes a peel functional layer, a hard coat layer, an index-matching layer in this order toward one side in the thickness direction T on the resin film 11.

The transparent electroconductive film X is used in a state where the film X is fixed to an article and the transparent electroconductive layer 20 is patterned as needed. The transparent electroconductive film X is bonded to an article, for example, with a fixing functional layer interposed therebetween.

Examples of the article include an element, a member, and a device. That is, examples of the article with the transparent electroconductive film include an element with a transparent electroconductive film, a member with a transparent electroconductive film, and a device with a transparent electroconductive film.

Examples of the element include a light control element and a photoelectric conversion element. Examples of the light control element include a current driven-type light control element and an electric field driven-type light control element. Examples of the current driven-type light control element include an electrochromic (EC) light control element. Examples of the electric field driven-type light control element include a polymer dispersed liquid crystal (PDLC) light control element, a polymer network liquid crystal (PNLC) light control element, and a suspended particle device (SPD) light control element. Example of the photoelectric conversion element includes a solar cell. Examples of the solar cell include an organic thin film solar cell and a dye-sensitized solar cell. Examples of the member include an electromagnetic wave shielding member, a hot wire control member, a heater member, and an antenna member. Examples of the device include a touch sensor device, an illuminating device, and an image display device.

Examples of the fixing functional layer described above include an adhesive layer and a bonding layer. As a material of the fixing functional layer, any material can be used without particular limitation as long as it has transparency and exhibits the fixing function. The fixing functional layer is preferably formed of resin. Examples of the resin include acrylic resin, silicone resin, polyester resin, polyurethane resin, polyamide resin, polyvinyl ether resin, vinyl acetate/vinyl chloride copolymer, modified polyolefin resin, epoxy resin, fluorine resin, natural rubber, and synthetic rubber. As the above-mentioned resin, acrylic resin is preferred because it shows adhesive properties such as cohesiveness, tackiness, and moderate wettability; excellent in transparency; and excellent in weather resistance and heat resistance.

The fixing functional layer (fixing functional layer forming resin) may be mixed with a corrosion inhibitor in order to inhibit corrosion of the transparent electroconductive layer 20. The fixing functional layer (fixing functional layer forming resin) may be mixed with a migration inhibitor (e.g., material disclosed in Japanese Unexamined Patent Publication No. 2015-022397) in order to inhibit migration of the transparent electroconductive layer 20′. The fixing functional layer (fixing functional layer forming resin) may also be mixed with an ultraviolet absorber in order to suppress deterioration of the article when used outdoors. Examples of the ultraviolet absorber include a benzophenone compound, a benzotriazole compound, a salicylic acid compound, an anilide oxalate compound, a cyanoacrylate compound, and a triazine compound.

When the transparent resin substrate 10 of the transparent electroconductive film X is fixed to the article with the fixing functional layer interposed therebetween, the transparent electroconductive layer 20 (including the patterned transparent electroconductive layer 20) is exposed in the transparent electroconductive film X. In this case, a cover layer may be disposed on the exposed surface of the transparent electroconductive layer 20. The cover layer is a layer that covers the transparent electroconductive layer 20, and is capable of improving reliability of the transparent electroconductive layer 20 and suppressing functional deterioration due to damage to the transparent electroconductive layer 20. Such a cover layer is preferably formed of a dielectric material, more preferably a composite material of a resin and an inorganic material. Examples of the resin include the above-mentioned resins for the fixing functional layer. Examples of the inorganic material include inorganic oxide and fluoride. Examples of the inorganic oxide include silicon oxide, titanium oxide, niobium oxide, aluminum oxide, zirconium dioxide, and calcium oxide. Examples of the fluoride includes magnesium fluoride. The cover layer (mixture of the resin and the inorganic material) may be mixed with the corrosion inhibitor, migration inhibitor, and ultraviolet absorber described above.

### EXAMPLES

In the following, the present invention will be described specifically based on Examples. The present invention is not limited by Examples. The specific numeral values described below, such as mixing ratios (contents), physical property values, and parameters can be replaced with the corresponding mixing ratios (contents), physical property values, and parameters in the above-described “DESCRIPTION OF THE EMBODIMENTS”, including the upper limit values (numeral values defined with “or less”, and “less than”) or the lower limit values (numeral values defined with “or more”, and “more than”).

### Example 1

A first curable composition was applied to one surface of a long cycloolefin polymer (COP) film (trade name “ZEONOR ZF16”, thickness: 40 μm, manufactured by Zeon Corporation) as a transparent substrate to form a first coated film. The first curable composition contains 100 parts by mass of polyfunctional urethane acrylate-containing coating liquid (trade name “UNIDIC RS29-120”, manufactured by DIC Corporation) and 0.07 parts by mass of crosslinked acrylic-styrene resin particles (trade name “SSX105”, particle size: 3 μm, manufactured by Sekisui Jushi Corporation). Subsequently, the first coated film was dried and then cured by ultraviolet irradiation to form an anti-blocking (AB) layer (1 μm thick). Next, a second curable composition was applied to the other surface of the COP film to form a second coated film. The second curable composition is a composition prepared in the same manner as the first curable composition except that the crosslinked acrylic-styrene resin particles (trade name “SSX105”) were not contained. Subsequently, the second coated film was dried and then cured by ultraviolet irradiation to form a hard coat (HC) layer (1 μm thick). In this manner, a transparent resin substrate was prepared.

Next, an amorphous transparent electroconductive layer having a thickness of 51 nm was formed on the HC layer of the transparent resin substrate by a reactive sputtering method (transparent electroconductive layer formation step). In the reactive sputtering method, a sputtering film formation apparatus (take-up type DC magnetron sputtering apparatus) capable of conducting a film deposition process while the transparent resin substrate was traveled in a roll-to-roll system was used. The travel speed of the transparent resin substrate in the apparatus was 4.0 m/min, and the tension (travel tension) acting in the travel direction of the transparent resin substrate was 200 N. Sputtering film formation conditions are as follows.

As a target, a first sintered body of indium oxide and tin oxide (with a tin oxide concentration of 10% by mass) was used. As a power source for applying a voltage to the target, a DC power source was used and the output of the DC power source was 25.1 kW. A horizontal magnetic field intensity on the target was 90 mT. A film deposition temperature (temperature of the transparent resin substrate having the transparent electroconductive layer laminated thereon) was −5° C. A film deposition chamber included in the apparatus was vacuum-evacuated internally to an ultimate degree of vacuum of 0.9×10⁻⁴ Pa, and Kr as a sputtering gas and oxygen as a reactive gas were then introduced into the film deposition chamber, so that the atmospheric pressure in the film deposition chamber was 0.2 Pa. A ratio of an amount of oxygen introduced with respect to the total amount of Kr and oxygen introduced into the film deposition chamber was about 2 flow rate %. The amount of oxygen introduced was within a region R of a surface resistance-oxygen introduced amount curve as shown in FIG. 5, and was adjusted so that a formed ITO film had a surface resistance value of 130 Ω/□. The surface resistance-oxygen introduced amount curve shown in FIG. 5 can be previously prepared by investigating the dependence of the surface resistance of the transparent electroconductive layer on the amount of oxygen introduced when the transparent electroconductive layer is formed by the reactive sputtering method under the same conditions as above except the amount of oxygen introduced.

Next, the transparent electroconductive layer on the transparent resin substrate was crystallized by heating in a hot-air oven (crystallization step). In this step, the heating temperature was 130° C. and the heating time was 90 minutes.

As described above, a transparent electroconductive film of Example 1 was prepared. The transparent electroconductive layer (51 nm thick) of the transparent electroconductive film of Example 1 was made of a Kr-containing crystalline ITO.

### Example 2

A transparent electroconductive film of Example 2 was prepared in the same manner as the transparent electroconductive film of Example 1 except the following in the transparent electroconductive layer formation step. The output of the DC power source for sputtering film formation was 19.1 kW. An amorphous transparent electroconductive layer having a thickness of 41 nm was formed while the amount of oxygen introduced was adjusted so that a formed ITO film had a surface resistance value of 170 Ω/□.

The transparent electroconductive layer (41 nm thick) of the transparent electroconductive film of Example 2 was made of a Kr-containing crystalline ITO.

### Comparative Example 1

A transparent electroconductive film of Comparative Example 1 was prepared in the same manner as the transparent electroconductive film of Example 1 except the following in the transparent electroconductive layer formation step. The output of the DC power source during sputtering film formation was 24.2 kW. As the sputtering gas, Ar was used. A formed transparent electroconductive layer had a thickness of 51 nm.

The transparent electroconductive layer (51 nm thick) of the transparent electroconductive film of Comparative Example 1 was made of an Ar-containing crystalline ITO.

### Comparative Example 2

A transparent electroconductive film of Comparative Example 2 was prepared in the same manner as the transparent electroconductive film of Example 1 except the following. In the sputtering film formation, the output of the DC power source was 24.2 kW, Ar was used as the sputtering gas, and a formed transparent electroconductive layer had a thickness of 51 nm. In the crystallization step, the transparent electroconductive film was heated (heating temperature: 130° C., heating time: 90 minutes) under a tension of 200 N on the transparent electroconductive film in an MD direction (travel direction during sputtering film formation).

The transparent electroconductive layer (51 nm thick) of the transparent electroconductive film of Comparative Example 2 was made of an Ar-containing crystalline ITO.

### <Thickness of Transparent Electroconductive Layer>

The thickness of each of the transparent electroconductive layers in Examples 1 and 2, and Comparative Examples 1 and 2 was measured by FE-TEM observation. Specifically, first, a sample for cross-section observation of each of the transparent electroconductive layers in Example 1 and 2, and Comparative Examples 1 and 2 was prepared by an FIB micro-sampling method. In the FIB micro-sampling method, an FIB device (trade name “FB2200” manufactured by Hitachi Ltd.) was used and the accelerating voltage was 10 kV. Next, the thickness of the transparent electroconductive layer in the sample for cross-section observation was measured by FE-TEM observation. In the FE-TEM observation, an FE-TEM device (trade name “JEM-2800” manufactured by JEOL Ltd.) was used, and the accelerating voltage was set to 200 kV.

### <Specific Resistance>

In each of the transparent electroconductive films of Examples 1 and 2, and Comparative Examples 1 and 2, the specific resistance of the transparent electroconductive layer was determined. Specifically, a surface resistance of the transparent electroconductive layer was measured by a four-terminal method according to JIS K 7194 (1994), and then, the surface resistance value was multiplied by the thickness of the transparent electroconductive layer, to thereby determine the specific resistance (Ω·cm). The results are shown in Table 1.

### <Confirmation of Kr Atoms in Transparent Electroconductive Layer>

Whether each of the transparent electroconductive layers in Examples 1 and 2 contained Kr atoms was confirmed as follows. First, using a scanning X-ray fluorescence spectrometer (trade name “ZSX Primus IV” manufactured by Rigaku Corporation), X-ray fluorescence analysis measurement was repeated 5 times under the following measurement conditions, an average value of the scan angles was calculated, and an X-ray spectrum was generated. It was then confirmed that a peak appeared near a scan angle of 28.2° in the generated X-ray spectrum, thereby confirming that Kr atoms were contained in the transparent electroconductive layer.

### <Measurement Conditions>

Spectrum: Kr-KA

Measurement diameter: 30 mm

Atmosphere: Vacuum

Target: Rh

Tube voltage: 50 kV

Tube current: 60 mA

Primary filter: Ni40

Scan angle (deg.): 27.0 to 29.5

Step (deg.): 0.020

Speed (deg/min): 0.75

Attenuator: 1/1

Slit: S2

Analyzing crystal: LiF (200)

Detector: SC

PHA: 100 to 300

### <Compressive Residual Stress in Transparent Electroconductive Layer>

The compressive residual stress in the transparent electroconductive layer (crystalline ITO film) of each of the transparent electroconductive films of Examples 1 and 2, and Comparative Examples 1 and 2 was indirectly determined from a crystal lattice strain of the transparent electroconductive layer. Specific details are as follows.

First, a rectangular measuring sample (50 mm×50 mm) was cut out from the transparent electroconductive film. Then, using a powder X-ray diffractometer (trade name “SmartLab”, manufactured by Rigaku Corporation), diffracted intensities of the measuring sample were measured at intervals of 0.02° within a range of measurement scattering angle 20=60 to 61.6° (0.15°/min). Subsequently, a crystal lattice spacing d of the transparent electroconductive layer in the measuring sample was calculated based on a peak (peak of the (622) plane of ITO) angle 2θ of the obtained diffraction image and a wavelength λ of an X-ray source, and a lattice strain ε was calculated based on d. For the calculation of d, the following equation (1) was used, and for the calculation of t, the following equation (2) was used.

[Mathematical Formula 1]

2d sin θ=λ (1)

ε=(d−d₀)/d₀ (2)

In equations (1) and (2), k is a wavelength (=0.15418 nm) of the X-ray source (Cu Ku ray), and do is a lattice plane spacing (=0.1518967 nm) of ITO in a stress-free state. The above-mentioned X-ray diffraction measurement was performed for each of angles Ψ of 65°, 70°, 75°, and 85° formed by a film plane-normal and an ITO lattice plane-normal, and a lattice strain ε at each angle Ψ was calculated. The angle Ψ formed by the film plane-normal and the ITO lattice plane-normal was adjusted by rotating a sample with a TD direction (direction orthogonal to the MD direction in plane) of the transparent resin substrate in the measuring sample (a part of the transparent electroconductive film) as a rotation axis center (adjustment of angle Ψ). A residual stress σ in the ITO film in-plane direction was determined by the following equation (3) from the slope of a line obtained by plotting a relationship between Sin² Ψ and the lattice strain ε. An absolute value of the determined residual stress σ (having a negative value) are shown in Table 1 as a first compressive residual stress S₁ (MPa) in the MD direction.

$$\begin{matrix}[ Mathematical Formula 2 ] & \\ ε = \frac{1 + ν}{E} {σsin}^{2} Ψ - \frac{2 ν}{E} σ & ( 3 )\end{matrix}$$

In equation (3), E was a Young's modulus (=115 GPa) of ITO, and ν was a Poisson's ratio (=0.35) of ITO.

A second compressive residual stress S₂ (MPa) in the TD direction was derived in the same manner as the first compressive residual stress S₁, except that the above-mentioned adjustment of angle Ψ in the X-ray diffraction measurement was performed by rotating the sample with the MD direction (direction orthogonal to the TD direction in plane) as the rotation axis center, instead of the TD direction of the transparent resin substrate in the measuring sample. The values are shown in Table 1. Ratios (S₂/S₁) of the second compressive residual stress S₂ to the first compressive residual stress S₁ are also shown in Table 1.

### <Amount of Warp in Transparent Electroconductive Film>

The extent of warp after heating treatment was examined in each of the transparent electroconductive films in Examples 1 and 2, and Comparative Examples 1 and 2. Specifically, first, a rectangular sample (100 mm×100 mm) was cut out from each of the transparent electroconductive films. Then, the sample was placed on the surface of an iron plate, and thereafter, the sample on the iron plate was subjected to heating treatment by heating the iron plate. In the heating treatment, the heating temperature was 130° C. and the heating time was 90 minutes. Next, the sample was allowed to stand under a room temperature (24° C.) environment for 60 minutes. Subsequently, the sample was positioned on a placement surface (substantially horizontal surface) of a work table, and thereafter, a distance from the placement surface to each of the vertices at four corners of the sample was measured. Specifically, when the sample was positioned on the placement surface so that the transparent resin substrate side of the sample was in contact with the placement surface, a vertical distance (mm) between a vertex that was spaced from the placement surface and the placement surface was measured as a positive value. Further, when the sample was positioned on the placement surface so that the transparent electroconductive layer side of the sample was in contact with the placement surface, a vertical distance (mm) between a vertex that was spaced from the placement surface and the placement surface was measured as a negative value. A distance between a vertex that was not spaced from the placement surface and the placement surface was 0 mm. Then, an average value of the measured distances for four vertices of the sample was calculated as an average amount, or extent, of warp (mm). The values are shown in Table 1.

TABLE 1

| | Thickness of | Surface | | | | | |
|---|---|---|---|---|---|---|---|
| | transparent | resistance | | Compressive residual | | | |
| | electroconductive | during film | Specific | stress | | | Amount |
| | layer | deposition | resistance | S₁ [MD] | S₂ [TD] | | of warp |
| | (nm) | (Ω/□) | (×10⁻⁴ Ω · cm) | (MPa) | (MPa) | S₂/S₁ | (mm) |
| Example 1 | 51 [Kr contained] | 130 | 1.5 | 552 | 482 | 0.87 | −16 |
| Example 2 | 41 [Kr contained] | 170 | 1.5 | 619 | 564 | 0.91 | −9 |
| Comparative | 51 [Ar contained] | 130 | 2.2 | 704 | 572 | 0.81 | −27 |
| Example 1 | | | | | | | |
| Comparative | 51 [Ar contained] | 130 | 2.2 | 804 | 628 | 0.78 | −35 |
| Example 2 | | | | | | | |

### INDUSTRIAL APPLICABILITY

The transparent electroconductive film of the present invention can be used as, for example, a supply of a conductor film for forming a pattern of a transparent electrode in various devices such as a liquid crystal display, a touch panel, and an optical sensor.

### DESCRIPTION OF REFERENCE NUMERALS

X transparent electroconductive film
T thickness direction
10 transparent resin substrate
11 resin film
12 functional layer
20 transparent electroconductive layer
21 first region
22 second region

1. A transparent electroconductive film comprising:
a transparent resin substrate and a transparent electroconductive layer in this order in a thickness direction,
wherein the transparent electroconductive layer has, in an in-plane direction orthogonal to the thickness direction, a first direction in which a compressive residual stress is maximum, and a second direction orthogonal to the first direction, and
in the transparent electroconductive layer, a ratio of a second compressive residual stress in the second direction to a first compressive residual stress in the first direction is 0.82 or more.

2. The transparent electroconductive film according to claim 1, wherein the transparent electroconductive layer contains krypton.

3. The transparent electroconductive film according to claim 1, wherein the transparent electroconductive layer contains an indium-containing electroconductive oxide.

4. The transparent electroconductive film according to claim 1, wherein the transparent electroconductive layer has a specific resistance of less than 2.2×10⁻⁴ Ω·cm.
